(19) United States
(12) Patent Application Publication
(10) Pub. No.: US 2022/0122805 A1
(43) Pub. Date: Apr. 21, 2022

(54) ION BEAM DELAYERING SYSTEM AND METHOD, AND ENDPOINT MONITORING SYSTEM AND METHOD THEREFOR

(71) Applicant: TECHINSIGHTS INC., Ottawa, Ontario (CA)

(72) Inventor: Christopher PAWLOWICZ, Ontario (CA)

(21) Appl. No.: 17/425,280

(22) PCT Filed: Jan. 21, 2020
(86) PCT No.: PCT/CA2020/050060

§ 371 Date: Jul. 22, 2021

Related U.S. Application Data
(60) Provisional application No. 62/795,369, filed on Jan. 22, 2019.

(51) Int. Cl. H01J 37/304; H01J 37/305; C23F 4/00; H01L 21/3213; H01L 21/66; G01N 19/06

(52) U.S. Cl. CPC H01J 37/304; H01J 37/3053; C23F 4/00; H01J 2237/30466; H01L 22/14; G01N 19/06; H01L 21/32136

(57) ABSTRACT

Described are various embodiments of an ion beam delayering system and method, and endpoint monitoring system and method. One embodiment includes a method for monitoring an ion beam de-layering process for an unknown heterogeneously layered sample, the method comprising: grounding the sample to allow an electrical current to flow from the sample, at least in part, as a result of the ion beam de-layering process; milling a currently exposed layer of the sample using the ion beam, resulting in a given measurable electrical current to flow from the sample as said currently exposed layer is milled, wherein said given measurable electrical current is indicative of an exposed surface material composition of said currently exposed layer; detecting a measurable change in said measureable electrical current during said milling as representative of a corresponding exposed surface material composition change; and associating said measurable change with a newly exposed layer of the sample.

### RELATED APPLICATION

The present application is an International Patent Application which claims benefit of priority to U.S. Provisional Patent Application Ser. No. 62/795,369, filed Jan. 22, 2019 and entitled “ION BEAM DELAYERING SYSTEM AND METHOD, AND ENDPOINT MONITORING SYSTEM AND METHOD THEREFOR”, the disclosure of which is hereby fully incorporated by reference

### FIELD OF THE DISCLOSURE

The present disclosure relates to ion beam milling, and, in particular, to an ion beam delayering system and method, and endpoint monitoring system and method therefor.

### BACKGROUND

Removing a layer in a sample such as a semiconductor die involves removing very small amounts and very thin layers of an integrated circuit, which contains metals and dielectrics, for example, to reveal the underlying circuitry in a precise and controlled manner.

Ion beam milling is one method used to de-layer such a sample. In general, ion beam mills may be used for various other purposes in the semiconductor industry, such as film deposition or surface modification or activation. Using an ion beam source with reactive and/or non-reactive gases, the source gas is ionized and the positive ions are extracted and accelerated toward the sample residing on a rotatable cooled stage in a vacuum chamber. The angle of the sample stage can be adjusted for the desired impact of the ions on the surface of the sample. There are various Ion Milling systems known in the art, such as Focussed Ion Beam Milling (FIB) systems and Broad Ion Beam Milling (BIB) systems.

In BIB milling systems, a layer of a sample is masked; when the sample is exposed to the beam, material is removed over the large area that is not protected by the mask. Milled area is measured in centimeters. The material removed is typically homogenous in nature (a layer of a single material or single compound is milled until removed). BIB mills have been limited to removing a layer of homogenous material as the removal rate is maintained constant for a given homogenous layer until the next layer is reached. In FIB milling systems, a more focused ion beam is generated (usually covering only a fraction of the surface being milled) and thus involves raster scanning the focused ion beam across a sample surface, by applying electromagnetic energy through a system of coils (and electrostatic lenses), to achieve a full delayering thereof. In both cases, the ion beam gun is stationary but the sample can be rotated and tilted to different angles.

In material removal applications, broad ion beams are directed at a sample in order to remove sample material in a non-selective manner. Generally, when a mask is pre-applied to the sample or a masking material is deposited on the sample beforehand in a predefined pattern. Known systems are directed to unselectively remove homogenous material layers of the sample without eroding the mask or the sample under the mask to facilitate creation of structures on an IC. The angle of the sample may be adjusted to maximize the removal rates for a substantially homogenous material layer.

In general, an endpoint detection system may also be used to detect when the substantially homogenous material layer has been substantially removed and the material from a subsequent layer is being removed, at which point removal is stopped.

One method for endpoint detection often used in the art is Secondary Ion Mass Spectroscopy (SIMS). However, endpoint detection methods such as SIMS have a number of drawbacks. For example, in ion beam milling, the large number of extracted material particles has the effect of producing noisy SIMS measurements. In this context, it is then challenging to use SIMS effectively for endpoint detection.

This background information is provided to reveal information believed by the applicant to be of possible relevance. No admission is necessarily intended, nor should be construed, that any of the preceding information constitutes prior art or forms part of the general common knowledge in the relevant art.

### SUMMARY

The following presents a simplified summary of the general inventive concept(s) described herein to provide a basic understanding of some aspects of the disclosure. This summary is not an extensive overview of the disclosure. It is not intended to restrict key or critical elements of embodiments of the disclosure or to delineate their scope beyond that which is explicitly or implicitly described by the following description and claims.

A need exists for an ion beam delayering system and method, and endpoint monitoring system and method therefor, that overcome some of the drawbacks of known techniques, or at least, provides a useful alternative thereto. Some aspects of this disclosure provide examples of such systems and methods.

For instance, in accordance with a broad aspect of the instant disclosure, an ion beam milling system and method, and endpoint monitoring system and method therefore, are provided, for example, where current flowing from a sample being de-layered using an ion beam mill can be used to monitor, and optionally control the milling process.

In accordance with one aspect, there is provided a method for monitoring an ion beam de-layering process for an unknown heterogeneously layered sample, the method comprising: grounding the sample to allow an electrical current to flow from the sample, at least in part, as a result of the ion beam de-layering process; milling a currently exposed layer of the sample using the ion beam, resulting in a given measurable electrical current to flow from the sample as said currently exposed layer is milled, wherein said given measurable electrical current is indicative of an exposed surface material composition of said currently exposed layer; and detecting a measurable change in said measureable electrical current during said milling as representative of a corresponding exposed surface material composition change; and associating said measurable change with a newly exposed layer of the sample.

In one embodiment, the method further comprises terminating said milling in response to said detecting said measurable change.

In one embodiment, the method further comprises imaging said newly exposed layer after said terminating; and repeating said milling and detecting until a subsequent said measurable change is detected.

In one embodiment, detecting comprises detecting that said measurable change is greater than a designated electrical current change threshold.

In one embodiment, the exposed surface material composition change comprises a change in a fraction of said exposed surface being composed of a conductive material.

In one embodiment, the conductive material is a metal and wherein another fraction of said exposed surface is composed of a semiconductor or dielectric material.

In one embodiment, the measurable electrical current changes between a higher current range when said exposed surface comprises an electrical circuit layer and a lower current range when said exposed surface comprises a dielectric layer.

In one embodiment, the method further comprises amplifying said measurable electrical current.

In one embodiment, the sample is an integrated circuit.

In one embodiment, the ion beam is a broad ion beam (BIB).

In one embodiment, the ion beam is a focused ion beam (FIB).

In one embodiment, the FIB is a plasma FIB.

In one embodiment, milling comprises scanning the ion beam over said currently exposed layer resulting in said given measurable electrical current to vary for a given surface scan, at least in part, in accordance with variations in said exposed surface material composition; and wherein said detecting comprises comparing said given measurable electrical current for each said given surface scan.

In one embodiment, comparing comprises comparing an average or integration of said given measurable electrical current for each said given surface scan.

In accordance with another aspect, there is provided a system for monitoring an ion beam de-layering process for an unknown heterogeneously layered sample, the system comprising: an electrical conductor for grounding the sample to allow a measureable electrical current to flow from the sample, at least in part, as a result of the ion beam de-layering process; and a current measuring apparatus operatively connected to said electrical conductor to detect a measurable change in said measureable electrical current as said currently exposed layer is milled, wherein said measurable electrical current is indicative of an exposed surface material composition of said currently exposed layer, and wherein said measurable change is indicative of milling a newly exposed layer of the sample.

In one embodiment, the system further comprises a current amplifying device operatively connected to said electrical conductor between the sample and said current measuring apparatus and operable to increase said amount of said measurable electrical current to be measured by said current measuring apparatus.

In one embodiment, the system further comprises a digital data processor operationally connected to said current measuring apparatus and operable to automatically identify from said measurable change said corresponding constituent material change in said exposed surface being milled.

In one embodiment, the digital data processor is further operatively coupled to an ion beam mill and operable to terminate the de-layering process upon identifying said corresponding constituent material change.

In one embodiment, the measurable change is defined by a designated electrical current increase threshold.

In one embodiment, the constituent material change comprises a change in a fraction of said exposed surface being composed of a conductive material.

In one embodiment, the conductive material is a metal and wherein another fraction of said exposed surface is composed of a semiconductor or dielectric material.

In one embodiment, the sample is an integrated circuit.

In one embodiment, the system further comprises an ion beam mill.

In one embodiment, the ion beam is a broad ion beam (BIB).

In one embodiment, the ion beam is a focused ion beam (FIB).

In one embodiment, the FIB is a plasma FIB.

In accordance with another aspect, there is provided an ion beam de-layering system for de-layering an unknown heterogeneously layered sample, the system comprising: an ion beam mill for generating an ion beam during an ion beam de-layering process; an electrical conductor for grounding the sample to allow a measureable electrical current to flow from the sample, at least in part, as a result of the ion beam de-layering process; a current measuring apparatus operatively connected to said electrical conductor to monitor said measureable electrical current during the milling process; and a digital data processor operationally connected to said current measuring apparatus and operable to identify a measurable change in said measurable electrical current, wherein said measurable electrical current is indicative of an exposed surface material composition of a currently exposed layer, and wherein said measurable change is indicative of milling a newly exposed layer of the sample.

In one embodiment, the digital processor is further operable to terminate a de-layering process upon said measurable change exceeding a designated threshold.

In one embodiment, the digital processor is operatively coupled or integral to a control system that is in operative communication with said ion beam mill and operable to control operation thereof during the ion beam de-layering process.

In one embodiment, the system further comprises a current amplifying device operable to amplify said measurable electrical current to said current measuring apparatus.

In one embodiment, the ion beam is a broad ion beam (BIB).

In one embodiment, the ion beam is a focused ion beam (FIB).

In accordance with another aspect, there is provided a non-transitory computer-readable medium for monitoring ion beam de-layering of an unknown heterogeneously layered sample and having computer-executable instructions stored thereon to: acquire electrical current data from an electrical measuring device representative of an electrical current flowing from the sample during ion beam de-layering; automatically identify a change in said electrical current data representative of a corresponding constituent material change in an exposed surface being milled upon said change exceeding a designated threshold; and output a signal to an ion beam mill controller to terminate said ion beam de-layering upon said change exceeding said designated threshold.

Other aspects, features and/or advantages will become more apparent upon reading of the following non-restrictive description of specific embodiments thereof, given by way of example only with reference to the accompanying drawings.

### BRIEF DESCRIPTION OF THE FIGURES

Several embodiments of the present disclosure will be provided, by way of examples only, with reference to the appended drawings, wherein:

FIG. 1 is a schematic diagram of a cross-section of an exemplary sample to be de-layered, in accordance with one embodiment;

FIG. 2 is a schematic diagram of an ion beam milling and monitoring system, in accordance with one embodiment;

FIGS. 3A and 3B are schematic diagrams illustrating exemplary changes in a measured current as monitored by the system of FIG. 2, in the case of BIB and FIB milling, respectively and in accordance with different embodiments;

FIG. 4 is a flow diagram describing a method of monitoring de-layering of an unknown sample by a broad ion beam mill, in accordance with one embodiment;

FIG. 5 is a schematic diagram of an ion beam milling endpoint detection system, in accordance with one embodiment;

FIG. 6 is a flow diagram describing an ion milling endpoint detection method, in accordance with one embodiment; and

FIG. 7 is a schematic diagram of an ion beam milling endpoint detection and control system, in accordance with one embodiment.

Elements in the several figures are illustrated for simplicity and clarity and have not necessarily been drawn to scale. For example, the dimensions of some of the elements in the figures may be emphasized relative to other elements for facilitating understanding of the various presently disclosed embodiments. Also, common, but well-understood elements that are useful or necessary in commercially feasible embodiments are often not depicted in order to facilitate a less obstructed view of these various embodiments of the present disclosure.

### DETAILED DESCRIPTION

Various implementations and aspects of the specification will be described with reference to details discussed below. The following description and drawings are illustrative of the specification and are not to be construed as limiting the specification. Numerous specific details are described to provide a thorough understanding of various implementations of the present specification. However, in certain instances, well-known or conventional details are not described in order to provide a concise discussion of implementations of the present specification.

Various apparatuses and processes will be described below to provide examples of implementations of the system disclosed herein. No implementation described below limits any claimed implementation and any claimed implementations may cover processes or apparatuses that differ from those described below. The claimed implementations are not limited to apparatuses or processes having all of the features of any one apparatus or process described below or to features common to multiple or all of the apparatuses or processes described below. It is possible that an apparatus or process described below is not an implementation of any claimed subject matter.

Furthermore, numerous specific details are set forth in order to provide a thorough understanding of the implementations described herein. However, it will be understood by those skilled in the relevant arts that the implementations described herein may be practiced without these specific details. In other instances, well-known methods, procedures and components have not been described in detail so as not to obscure the implementations described herein.

In this specification, elements may be described as “configured to” perform one or more functions or “configured for” such functions. In general, an element that is configured to perform or configured for performing a function is enabled to perform the function, or is suitable for performing the function, or is adapted to perform the function, or is operable to perform the function, or is otherwise capable of performing the function.

It is understood that for the purpose of this specification, language of “at least one of X, Y, and Z” and “one or more of X, Y and Z” may be construed as X only, Y only, Z only, or any combination of two or more items X, Y, and Z (e.g., XYZ, XY, YZ, ZZ, and the like). Similar logic may be applied for two or more items in any occurrence of “at least one . . . ” and “one or more . . . ” language.

The systems and methods described herein provide, in accordance with different embodiments, different examples in which a broad ion beam (BIB) or focused ion beam (FIB) de-layering and monitoring system and method can be used for monitoring and controlling the delayering of an unknown sample by measuring changes in the magnitude of electrical current flowing to or from the sample during milling. Such a system may be used as an endpoint monitoring system or unit to better control the milling parameters, such as but not limited to the milling rate, during the removal of one or more layers of the unknown sample.

Such a sample may be comprised of a composition of one or more materials. A sample may also refer to, but is not limited to: a semiconductor device, Integrated Circuit, a layer of metals and dielectrics of any thickness, one or more materials in an area of any size, optical devices, electronic devices, or any combinations thereof. A worker skilled in the art would readily understand the meaning of a sample for the purposes of the subject matter disclosed herein. While the present disclosure describes various embodiments for illustrative purposes, such description is not intended to be limited to such embodiments. On the contrary, the applicant's teachings described and illustrated herein encompass various alternatives, modifications, and equivalents, without departing from the embodiments, the general scope of which is defined in the appended claims. Except to the extent necessary or inherent in the processes themselves, no particular order to steps or stages of methods or processes described in this disclosure is intended or implied. In many cases the order of process steps may be varied without changing the purpose, effect, or import of the methods described.

Delayering may entail, but is not limited to: removal of one or more layers, partly or wholly, wherein the one or more layers or portions thereof may comprise one or more materials; removal of one or more layers, partly or wholly, comprising one or more materials, wherein the one or more layers may comprise small or large surface areas; removal of one or more layers, partly or wholly, wherein the one or more layers may be of any desired thickness; removal of one or more materials, partly or wholly, to any extent desired; removal of one or more substantially parallel layers, partly or wholly, wherein the one or more substantially parallel layers or portions thereof may comprise one or more materials; removal of one or more substantially planar layers, partly or wholly, wherein the one or more substantially planar layers or portions thereof may comprise one or more materials; removal of one or more substantially constant thickness parallel layers, partly or wholly, wherein the one or more substantially constant thickness parallel layers or portions thereof may comprise one or more materials; removal of one or more varying thickness parallel layers, partly or wholly, wherein the one or more varying thickness parallel layers or portions thereof may comprise one or more materials or any combinations thereof. For the purposes of the subject matter disclosed herein, the terms delayering and de-layering may be used interchangeably. Delayering may be set to take place for a certain time; after which, the sample may be removed from the ion beam mill, analyzed, and further delayering necessitated, until the desired level of delayering is achieved

In the case of an IC sample, delayering may be performed for reverse engineering the circuitry inherent within a device. An ion beam mill may be used to delayer a device layer by layer and exposing the circuitry or circuit connections on the surface of each layer. Upon delayering the device, pictures, images or other representation (e.g. circuit schematic model based on data representative of detected surface features) may be taken of each layer, thereby, capturing the circuitry or circuit connections on the surface of each layer. By piecing together, the pictures, images, or other representations of the different layers, using appropriate software tools, circuit connections between the various components that may be inherent within a device, both across and between layers, can be produced. The process may be repeated for various devices within a larger device and a hierarchical schematic of the circuit connections of the various devices within the larger device may be developed. Proprietary software tools may also be used to produce hierarchical circuit schematics. Such circuit schematics may be useful in identifying evidence of use of claim elements in the target device being delayered. According to some embodiments, delayering may be performed for, but is not limited to, failure analysis (defect identification), circuit edit, sample/device characteristics measurement, verification of design, and counterfeit detection.

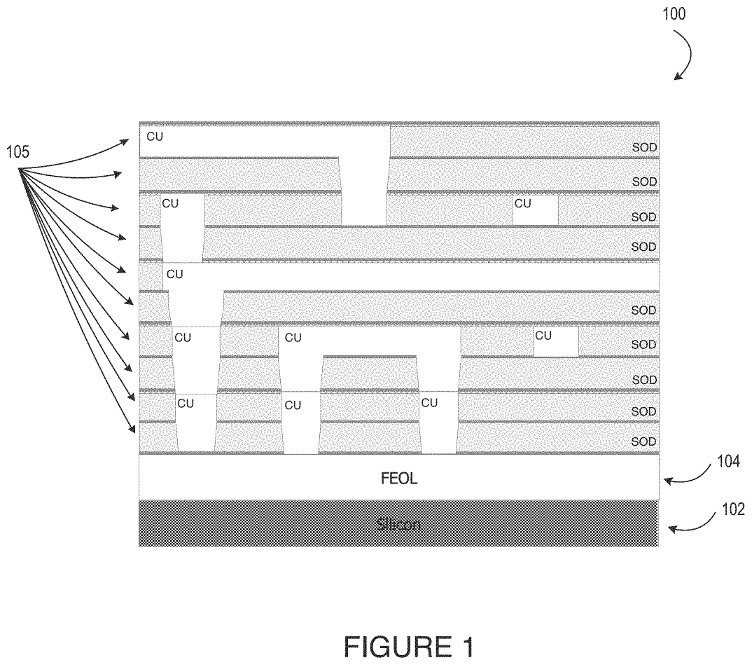

With reference to FIG. 1, and in accordance with one exemplary embodiment, a schematic diagram of a cross-section of an exemplary sample to be de-layered, generally referred to using the numeral 100, will now be described. In this exemplary embodiment, the sample is an integrated circuit (IC). In general, an IC may take the form of a multi-wiring layer structure, in which a wiring layer and an insulating layer are laminated. Each layer or portions thereof may be made up of one or more materials, or a mixture of materials such as, but not limited to, metal interconnects and dielectrics in varying shapes and structures. For example, in FIG. 1 the bottommost layer (i.e. substrate) 102 may be mostly comprised of a silicon layer. Above this layer is the Front-end-of-line (FEOL) region 104 comprising a multiplicity of transistors built directly on the silicon. Above this there is a number of interconnection layers 105, comprising different amounts of metal interconnects and dielectric materials (such as a spin-on dielectric (SOD) or chemical vapor deposited (CVD) dielectric), each separated for example by a thin layer of SO2 or silicon oxycarbide. A worker skilled in the art would readily understand the layers within an IC and how each layer may be characterized by the presence and quantity of different types of materials, such as, but not limited to those mentioned above.

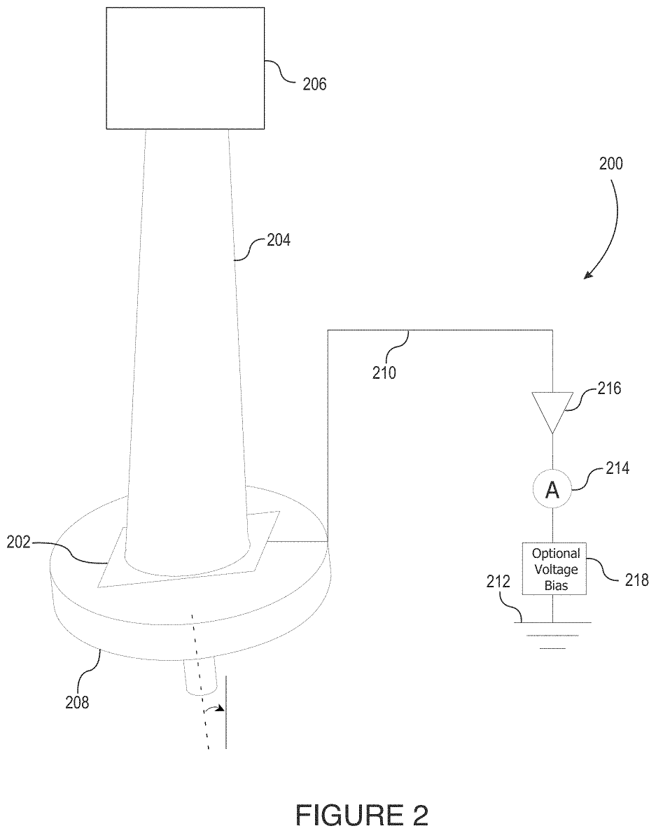

When an ion beam of positively charged ions impinges on the exposed surface of such a sample, the high energy primary ions collide with the solid surface, transferring energy from the primary particle to the atoms of the material to be milled. Some of the primary ions can be back scattered but most of them transfer their kinetic energy to the lattice through a collision sequence and are implemented into the target according to their energy, mass and impact angle. Ions that impact the exposed material with sufficient energy will dislodge atoms or molecules and generate the emission of secondary electrons and photons. Ion milling is an etching process where the ion beam is used so that the material in the exposed surface of the sample is to be etched away. The implementation of the primary ions, followed by the generation of secondary ions and ejected electrons may lead to the increase or build-up of positive charges in the sample's surface. Depending on the conductivity of the material being irradiated, these charges may be more or less mobile. When such a sample is being de-layered with an ion beam, the layers are slowly exposed sequentially from the top surface. The exposed surface of the sample may be non-homogenous (i.e. heterogeneous) and therefore constitute different compositions of materials or it may also be homogenous, which constitutes a single material composition. Upon delayering a surface of a sample, the underlying surface may be left substantially uniform or even regardless of the delayered surface being homogenous or non-homogenous. Upon delayering a surface of a sample, the underlying surface may also be left substantially non-uniform or uneven. With reference to FIG. 2, and in accordance with one exemplary embodiment, a schematic diagram of an ion beam milling and monitoring system, generally referred to using the numeral 200, will now be described. In this exemplary embodiment, the system 200 is used in the context of a sample 202 being impinged by a broad ion beam 204 generated by an ion beam mill 206. Ion beam 206 may be a broad ion beam (BIB) mill, a focused ion beam (FIB), a plasma FIB, or other ion beam technologies, as may be readily appreciated by the skilled artisan. Such an ion beam mill is generally configured by adjusting one or more of its operating characteristics. The one or more ion beam mill operating characteristics may be associated with a predetermined rate at which a material may be removed. Delayering a sample may be achieved by configuring the ion mill to remove one or more materials from the sample at their respective predetermined rates. The association of rates of removal to sets of ion mill operating characteristics may be obtained experimentally through trial and error or via simulation methods. The rates of removal and their associated sets of ion mill operating characteristics may be logged or stored for future manipulation of the ion mill in any storage medium such as a database, memory device, computing storage device or any storage medium as would be known to a worker skilled in the art. The ion beam mill 206 may also consist of one or more ion beam sources. For example, ion mill 206 may comprise one or more large diameter gridded ion beam source, such as an argon source, but other ion sources, such as elemental gold, gallium, iridium, xenon, as well any other suitable ion sources, may also be used. Moreover, various gas injection systems may deliver different process gasses during milling, while a plasma bridge neutralizer may be used to neutralize the ion beam. Vacuum gauges, a load-lock, vacuum pumps, one or more control panels, and one or more processors may also be associated with the ion mill. Furthermore, one or more ion beam sources may be associated with apertures and electrostatic lenses. It is to be understood that the operation of an ion mill and the various fundamental components of an ion mill would be readily known to a worker skilled in the art. The sample 202 may be mounted on a, variable angle, cooled sample stage 208 that can be tilted and rotated. As mentioned above, such a sample stage may be housed in a vacuum chamber. The skilled worker in the art will readily understand how a sample is affixed to such a rotating stage, including the different methods of insuring a good thermal and electrical contact.

The monitoring system 200 itself comprises an electrical conductor (e.g. an electrical wire) 210 connecting sample 202 to ground 212 in such a way that allows for any freely moving charges to flow from sample 202 as it is being irradiated or milled. A current measuring device 214, such as an analogue or digital ammeter or similar may be connected to conductor 210 between sample 202 and ground 212 to measure this current (stage current, sample current, absorbed current, etc.) and the changes thereto. In some embodiments, an optional biasing voltage 218 may also be added to increase or improve the current detected in current measuring device 214, depending on polarity of ions used and/or other operational considerations, as will be readily understood by the skilled technician. The falling or rising trend in the current thus measured will be, as explained below, indicative of a change in the nature of the layer currently being milled. These trends may be used to monitor the milling process itself, and/or to provide the means to the ion beam operator to measure when an endpoint is reached. In some embodiments, conductor 210 may be connected to a bottom region of sample 202. The skilled artisan will understand that many techniques may be employed to reliably connect sample 202 to an electrical conductor 210. In other embodiments, the electrical conductor 210 may instead be connected to stage 208 if both sample 202 and stage 208 already have a good electrical connection, for instance by using a thin layer of electrically conductive vacuum grease or similar. Alternatively, if the current flowing from sample 202 during irradiation is too small to be accurately measured, a current amplifying device 216 such as a pre-amplifier or similar may also be connected to conductor 210 between sample 202 and the current measuring device 214.

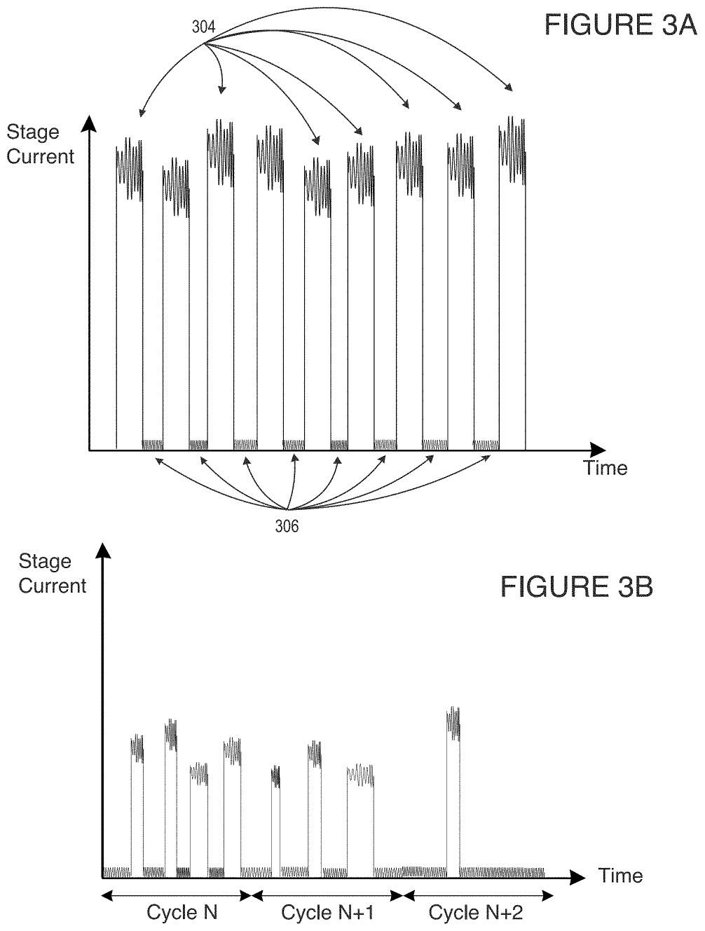

With reference to FIGS. 3A and 3B, and in accordance with different exemplary embodiments, schematic diagrams illustrating the changes in the measured current as monitored by the system of FIG. 2, generally referred to using the numeral 300, will now be described. As explained above, de-layering this type of structure will expose sequential surface areas with larger amounts of conductive material (wiring layer) followed by areas with larger amounts of dielectric material (insulating layer). If such a sample was to be electrically connected to ground, accumulated charges produced by the ion beam in the sample would cause a current to flow therefrom. However, the magnitude of such a current would be dependent on the type of material being irradiated. For instance, the high conductivity of a metallic material (pure metal or metallic alloy) would tend to produce a higher current, while the low conductivity of a dielectric material (i.e. silicon dioxide, silicon nitride, etc.) would restrict the free flow of charges. Thus, a direct measurement of the current flowing from the sample during ion milling will show changes or variations such as a rising or falling trend as the sample is de-layered.

In both cases where a BIB or FIB mill is used (or other ion beam technologies that may typically exhibit broader or narrower beam spot sizes), the current from the sample is measured from the moment the mill is activated, at which point the current is expected to rise rapidly. Therefrom, the measured current is expected to change depending on the type of material being milled (in contact with the ion beam). Layers composed primarily of highly conductive materials (such as metals), when hit by the positive ions, are expected to produce a higher current, while a reduced current is expected when the layer is primarily composed of electrically isolating materials. FIG. 3A shows a schematic plot of the measured current as a function of milling time (e.g. milling depth) when using a BIB mill. Such mills have beams that are typically broad enough to cover the entire surface of interest of the sample at the same time, therefore the measured current will be a sum of all the interactions with all the features (metal interconnects and/or dielectric) of the surface at a given time. Therefore, while some variation is expected in the shape or profile of the measured current for a given layer, constituent materials, or material compositions, as discussed above, generic features or trends are nonetheless to be expected and may thus be used or relied upon, at least in part, to differentiate between layers, and constituent materials or material compositions thereof. As seen in FIG. 3A, for example, each time a surface layer comprising metal interconnect-rich regions is milled, a higher current is measured, producing “peaks” and/or “plateaus” (304), while milling dielectric-rich regions will tend to produce significantly lower electric currents (306). Finally, once all the functional layers are milled and the beam reaches the bottom substrate layer, an intermediary and constant current should be measured.

Thus, the alternating layers within the sample will produce an alternating current signature. This alternating change in the measured current may then be readily used to identify the type of material (e.g. metallic vs insulating) and thus characterize the layer currently being milled. The exact amplitude of these peaks and valleys may vary depending on the details of the implementation and depending on the exact nature and quantity of material being milled at each layer. Thus, the exact current profile from layer to layer may deviate from the one of FIG. 3A and the change in current may not only take the form of shallow or broad peaks, but it may also take the form of an inflection point. However, the characteristic relative “rising and falling” variation between a higher current and a lower current measured as sequential layers are being milled is expected to remain for most types of samples, thus generally allowing for the visual and/or automated inspection and identification of layer boundaries/transitions during milling, and/or the establishment of current flow threshold or trend changes indicative of such boundaries/transitions. In addition, two or more regions of low current (high current) may also be compared to identify the presence of two or more insulating materials (metallic materials). As such, two generally low (high) current regions may both contain a substantial amount of dielectric (conductive) material, but the difference between the absolute measured current in each region may also provide the means to differentiate between each insulating (metallic) material. By identifying the general composition of the exposed surface layer, it may be possible to characterize the layer itself with respect to functional features present therefrom. This characterization may be used to identify the layer, for example to identify if the layer is a pre-determined endpoint layer where the milling process is to be stopped.

In contrast, FIG. 3B illustrates schematically the measured stage current obtained when using a FIB mill or similar. FIB milling involves raster scanning the focused ion beam across a sample surface and a whole layer is removed only when a full scan of the surface is completed. Thus, monitoring a FIB milling process may require not only measuring the stage current (which may be smaller as the ion beam covers less material compared to a BIB mill) as a function of time (or milling time) but also keeping track of successive scan cycles. The stage current will therefore vary a great deal within a given scan cycle, as the FIB mills smaller portions of the sample surface, hitting metallic and/or dielectric materials. However, it is the relative difference between regions of measured current indicative of successive scan cycles that can be used to determine a transition between layers. FIG. 3B gives an exemplary plot of such a measurement, wherein three successive scan cycles are illustrated (N, N+1 and N+2). The first two cycles comprise a relatively high portion of higher measured currents, indicative that associated milled layers comprised a relatively high portion of metal interconnects. In contrast, cycle N+2 shows a markedly lower number of higher current peaks/plateaus, indicative that the present layer being milled is located at or near a transition region located at a depth between two metal interconnect rich layers. In some FIB embodiments, additional signal analysis techniques, in real-time or near real-time, such as integrating the measured current during a full scan cycle and/or applying a running average or similar, may be used to improve the detection of successive surface layers.

Naturally, various ion beam parameters may impact the measured current profile and approach to differentiating between conductor-rich and dielectric-rich layers. For instance, the BIB example represents one end of the spectrum where the ion beam spot size is typically equal or greater than an entire surface of the sample being milled, resulting in a measured current that automatically averages over all surface features. As illustrated above, a particularly narrow beam implementation, such as in a FIB implementation, will result in a more variable current profile as the beam sequentially interacts with different portions of the sample's exposed surface. Accordingly, parameters such as scan/raster speeds, spot size relative to surface features, accumulated charge detection speeds may impact a general surface resolution or feature specificity of the acquired measured current profiles, and thus impact how such signals can be averaged and/or otherwise combined to provide layer or surface level information useful in distinguishing distinctly composed sample layers.

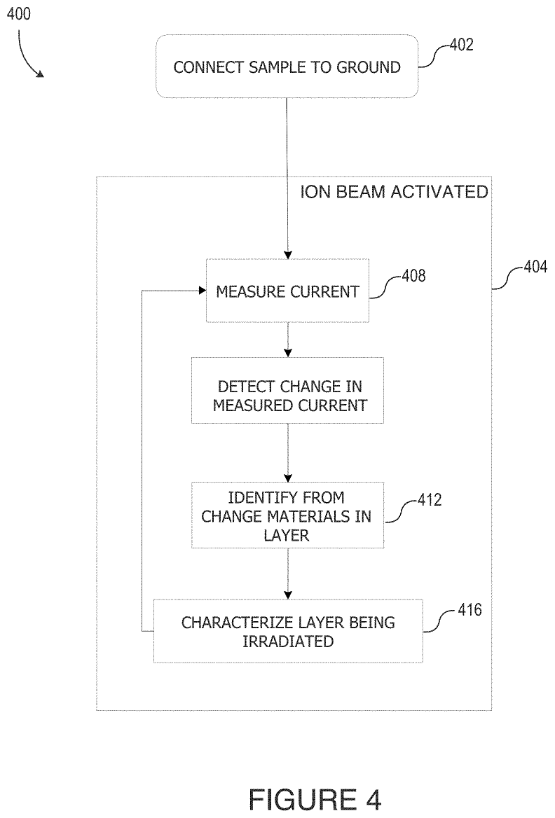

With reference to FIG. 4, and in accordance with one exemplary embodiment, a flow diagram describing a method of monitoring the de-layering of an unknown sample by a broad ion beam mill, generally referred to using numeral 400, is explained. First (402), prior to activating the ion beam mill, the sample to be de-layered, once installed on the stage is connected, using an electrical conductor (e.g., wire or similar), to ground. Once the milling process is started by initiating the mill, the current flowing from the sample to ground is measured (408) using as mentioned above an electrical current measuring device such as an ammeter. As explained above, the current measured is expected to vary when milling consecutive layers of the sample. In the case of a BIB mill, the measured current amplitude is directly expected to be indicative of the composition of all material types contained within the layer, while for a FIB mill, the current amplitude measured during an entire scan cycle may be used instead. These changes may be used to identify the constituent materials or type of materials on the exposed surface of the milled layer (412). From this information, it may be possible to characterize the exposed layer being irradiated (416) with respect to previous layers and determine therefrom if this layer is an endpoint layer. If it is the case, the skilled technician will be able to respond by changing one or more ion mill operating characteristics or parameters, for example to adjust the material removal rate, or he may stop the milling process altogether if this is what is desired. As noted in the below examples, such operational decisions may also or otherwise be automated by establishing designated endpoint detection thresholds or like values to be assessed by a digital data processor operatively associated with the current measuring device and ion beam mill.

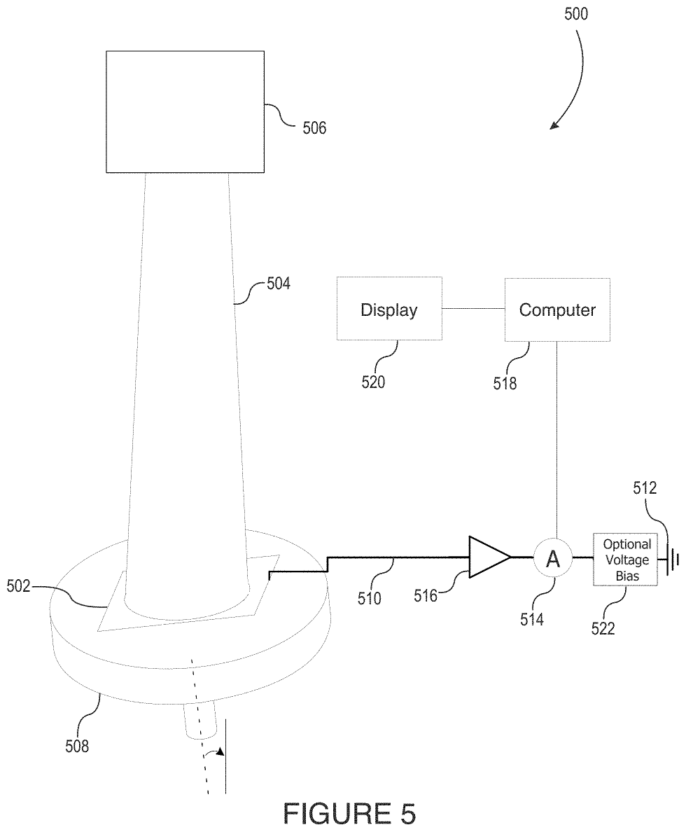

With reference to FIG. 5, and in accordance with one exemplary embodiment, a schematic diagram of a ion beam milling endpoint detection system, generally referred to using the numeral 500, will now be described. The system 500 is similar to the one described above with reference to FIG. 2, in that it also comprises an electrical conductor (e.g. an electrical wire, etc.) 510 connected from sample 502 to ground 512 in such a way that allows for any freely moving charges to flow from a sample 502 as it is being de-layered with an ion beam 504 generated by a (broad or focused) ion beam mill 506. Similarly, system 500 again comprises a current measuring device 514, such a digital ammeter or similar, which may again be connected to conductor 510 between sample 502 and ground 512 to measure this current (stage current, sample current, absorbed current, etc.) and the changes thereto. In some embodiments, an optional biasing voltage 522 may also be added to increase or improve the current measured in current measuring device 514, depending on polarity of ions used and/or other operational considerations, as will be known to the skilled technician. In addition, system 500 further comprises a digital data processor 518 operatively connected to the current measuring device 514, for example via a digital interface, and operable to automatically identify, in real-time or near real-time, from the changes in the measured current, the presence and quantity of different types of constituent materials and further operable to characterize, from said type of materials, the layer currently being milled. For example, such changes, boundaries and/or transitions may be preprogrammed to correspond with certain designated current increase/decrease thresholds, values and/or ranges, which may be determined from prior testing, sampling and/or observations using the system 500 and similar samples, or again, incrementally learned by the system or operator thereof based on current variation trends, profiles or the like. It will be appreciated that the processor 518 may take various forms, which may include, but is not limited to, a dedicated computing or digital processing device, a general computing device or other computing device as may be readily appreciated by the skilled artisan. In some embodiments, processor 518 may be operationally connected to a digital display interface 520, which may comprise a computer with a digital display screen, tablet, smartphone application or like general computing device, or again a dedicated device having a graphical or like general computing device. Finally, as described above, system 500 may comprise a current amplifying device 516 such as a pre-amplifier or similar, connected to conductor 510 between sample 502 and the current measuring device 514 and operable to increase the current flowing thereto.

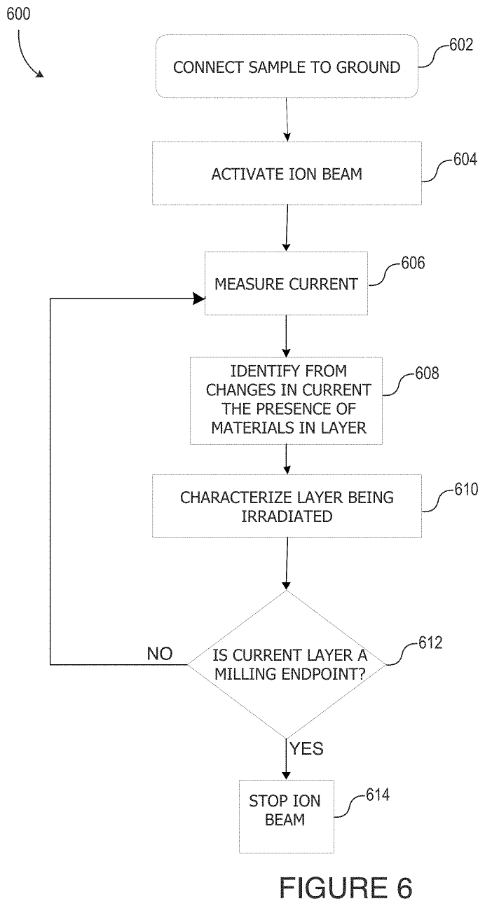

With reference to FIG. 6, and in accordance with one exemplary embodiment, a flow diagram describing a method of ion beam milling endpoint detection and control, generally referred to using the numeral 600, for the de-layering of an unknown sample by a broad ion beam mill, will now be described. This exemplary embodiment is similar to the one described above with reference to FIG. 4, in that it also comprises the steps of first connecting the sample to ground (602), but further includes the steps related to the control of the ion beam mill itself. This includes first activating the (broad or focused) ion beam (604) before proceeding with, as before, continuously measuring (606) the current flowing from the sample and identifying from changes therefrom the type of material present within the exposed layer (608) and characterizing therefrom the layer being milled (610). In addition, the present method includes the step of determining from said characterization if the current layer being milled has been pre-determined to be an endpoint layer (612). If this is not the case (e.g. transitioning to or within a dielectric layer in an integrated circuit where current flow is relatively lower), then the current is again continuously monitored (602). In the case where the layer is an endpoint layer (e.g. transitioning to or within a circuit layer in an integrated circuit where current flow is relatively higher), then the ion beam is turned off to stop the milling process (614). In some embodiments, it may be desirable to change the milling rate instead of stopping the milling process altogether, depending on the application at hand.

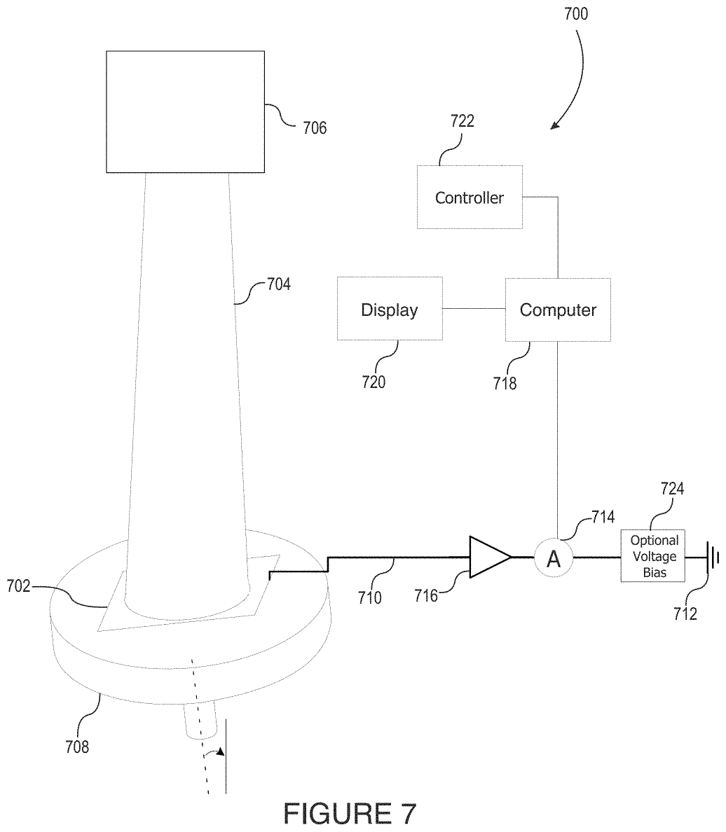

With reference to FIG. 7, and in accordance with yet another exemplary embodiment, a schematic diagram of an ion beam milling endpoint detection and control system, generally referred to using the numeral 700, will now be described. The system 700 is similar to the one described above with reference to FIG. 5, in that it also comprises an electrical conductor (e.g. an electrical wire, etc.) 710 connected from sample 702 to ground 712 in such a way that allows for any freely moving charges to flow from a sample 702 as it is being de-layered with a broad ion beam 704 generated by a broad or focused ion beam mill 706. Similarly, system 700 again comprises a current measuring device 714, such as a digital ammeter or similar that is again connected to conductor 710 between sample 702 and ground 712 to measure this current (stage current, sample current, absorbed current, etc.) and the changes thereto. In some embodiments, an optional biasing voltage 724 may also be added to increase or improve the current flowing in current measuring device 714, depending on polarity of ions used and/or other operational considerations, as will be known to the skilled technician. The system further comprises a digital data processor 718 operatively connected to the current measuring device 714, for example via a digital interface, and operable to automatically identify, in real-time or near real-time, from the changes in the measured current, the presence and quantity of different types of materials, and further operable to characterize, from said type of materials, the layer currently being milled and determine if it corresponds to a pre-determined endpoint. The currently described exemplary embodiment further comprises the BIB mill 706 and sample stage 708 themselves, in addition to a controller 720 operatively connected to said digital processor 718 (which may be integral thereto or operatively associated therewith), mill 706, and stage 708, and operable to provide endpoint control to the milling process by changing one or more ion mill operating characteristics or parameters, for example to adjust the material removal rate, and/or stopping the milling process altogether when an endpoint layer is reached. The artisan well versed in the art of BIB milling will be familiar with the different control parameters that may be used therefor.

Information as herein shown and described in detail is fully capable of attaining the above-described object of the present disclosure, the presently preferred embodiment of the present disclosure, and is, thus, representative of the subject matter which is broadly contemplated by the present disclosure. The scope of the present disclosure fully encompasses other embodiments which may become apparent to those skilled in the art, and is to be limited, accordingly, by nothing other than the appended claims, wherein any reference to an element being made in the singular is not intended to mean “one and only one” unless explicitly so stated, but rather “one or more.” All structural and functional equivalents to the elements of the above-described preferred embodiment and additional embodiments as regarded by those of ordinary skill in the art are hereby expressly incorporated by reference and are intended to be encompassed by the present claims. Moreover, no requirement exists for a system or method to address each and every problem sought to be resolved by the present disclosure, for such to be encompassed by the present claims. Furthermore, no element, component, or method step in the present disclosure is intended to be dedicated to the public regardless of whether the element, component, or method step is explicitly recited in the claims. However, that various changes and modifications in form, material, work-piece, and fabrication material detail may be made, without departing from the spirit and scope of the present disclosure, as set forth in the appended claims, as may be apparent to those of ordinary skill in the art, are also encompassed by the disclosure.

1. A method for monitoring an ion beam de-layering process for an unknown heterogeneously layered sample, the method comprising:
grounding the unknown heterogeneously layered sample to allow an electrical current to flow from the unknown heterogeneously layered sample, at least in part, as a result of the ion beam de-layering process;
milling a currently exposed layer of the unknown heterogeneously layered sample using an ion beam, resulting in a given measurable electrical current to flow from the unknown heterogeneously layered sample as said currently exposed layer is milled, wherein said given measurable electrical current is indicative of an exposed surface material composition of said currently exposed layer;
detecting a measurable change in said given measureable electrical current during said milling as representative of a corresponding exposed surface material composition change; and
associating said measurable change with a newly exposed layer of the unknown heterogeneously layered sample.

2. The method of claim 1, further comprising: terminating said milling in response to said detecting said measurable change.

3. The method of claim 2, further comprising:
imaging said newly exposed layer after said terminating; and
repeating said milling and said detecting until a subsequent said measurable change is detected.

4. The method of claim 1, wherein said detecting comprises detecting that said measurable change is greater than a designated electrical current change threshold.

5. The method of claim 1, wherein said corresponding exposed surface material composition change comprises a change in a fraction of said currently exposed layer being composed of a conductive material.

6. The method of claim 5, wherein said conductive material is a metal and wherein another fraction of said currently exposed layer is composed of a semiconductor or dielectric material.

7. The method of claim 5, wherein said given measurable electrical current changes between a higher current range when said currently exposed layer comprises an electrical circuit layer and a lower current range when said currently exposed layer comprises a dielectric layer.

8. The method of claim 1, further comprising amplifying said given measurable electrical current.

9. The method of claim 1, wherein the unknown heterogeneously layered sample is an integrated circuit.

10. The method of claim 1, wherein said ion beam is any one of a broad ion beam (BIB), a focused ion beam (FIB), or a plasma FIB.

11. (canceled)

12. (canceled)

13. The method of claim 1, wherein said milling comprises scanning said ion beam over said currently exposed layer resulting in said given measurable electrical current to vary for a given surface scan, at least in part, in accordance with variations in said exposed surface material composition; and wherein said detecting comprises comparing said given measurable electrical current for each said given surface scan.

14. The method of claim 13, wherein said comparing comprises comparing an average or integration of said given measurable electrical current for each said given surface scan.

15. A system for monitoring an ion beam de-layering process for an unknown heterogeneously layered sample, the system comprising:
an electrical conductor for grounding the unknown heterogeneously layered sample to allow a measureable electrical current to flow from the unknown heterogeneously layered sample, at least in part, as a result of the ion beam de-layering process; and
a current measuring apparatus operatively connected to said electrical conductor to detect a measurable change in said measureable electrical current as a currently exposed layer is milled, wherein said measurable electrical current is indicative of an exposed surface material composition of said currently exposed layer, and wherein said measurable change is indicative of milling a newly exposed layer of the unknown heterogeneously layered sample using an ion beam.

16. The system of claim 15, further comprising a current amplifying device operatively connected to said electrical conductor between the unknown heterogeneously layered sample and said current measuring apparatus and operable to increase an amount of said measurable electrical current to be measured by said current measuring apparatus.

17. The system of claim 15, further comprising:
a digital data processor operationally connected to said current measuring apparatus and operable to automatically identify from said measurable change a corresponding constituent material change in said currently exposed layer being milled.

18. The system of claim 17, wherein said digital data processor is further operatively coupled to an ion beam mill and operable to terminate the ion beam de-layering process upon identifying said corresponding constituent material change.

19. The system of claim 18, wherein said measurable change is defined by a designated electrical current increase threshold.

20. The system of claim 17, wherein said corresponding constituent material change comprises a change in a fraction of said currently exposed layer being composed of a conductive material.

21. The system of claim 20, wherein said conductive material is a metal and wherein another fraction of said currently exposed layer is composed of a semiconductor or dielectric material.

22. The system of claim 15, wherein the unknown heterogeneously layered sample is an integrated circuit.

23. (canceled)

24. The system of claim 15, wherein said ion beam is any one of a broad ion beam (BIB), a focused ion beam (FIB), or a plasma FIB.

25. (canceled)

26. (canceled)

27. An ion beam de-layering system for de-layering an unknown heterogeneously layered sample, the system comprising:
an ion beam mill for generating an ion beam during an ion beam de-layering process;
an electrical conductor for grounding the unknown heterogeneously layered sample to allow a measureable electrical current to flow from the unknown heterogeneously layered sample, at least in part, as a result of said ion beam de-layering process;
a current measuring apparatus operatively connected to said electrical conductor to monitor said measureable electrical current during said ion beam de-layering process; and
a digital data processor operationally connected to said current measuring apparatus and operable to identify a measurable change in said measurable electrical current, wherein said measurable electrical current is indicative of an exposed surface material composition of a currently exposed layer, and wherein said measurable change is indicative of milling a newly exposed layer of the unknown heterogeneously layered sample.

28. The system of claim 27, wherein said digital processor is further operable to terminate said ion beam de-layering process upon said measurable change exceeding a designated threshold.

29. The system of claim 27, wherein said digital processor is operatively coupled or integral to a control system that is in operative communication with said ion beam mill and operable to control operation thereof during said ion beam de-layering process.

30. The system of claim 27, further comprising a current amplifying device operable to amplify said measurable electrical current to said current measuring apparatus.

31. The system of claim 27, wherein said ion beam is any one of a broad ion beam (BIB), or a focused ion beam (FIB).

32. (canceled)

33. A non-transitory computer-readable medium for monitoring ion beam de-layering of an unknown heterogeneously layered sample and having computer-executable instructions stored thereon to:
acquire electrical current data from an electrical measuring device representative of an electrical current flowing from the unknown heterogeneously layered sample during ion beam de-layering;
automatically identify a change in said electrical current data representative of a corresponding constituent material change in an exposed surface being milled upon said change exceeding a designated threshold; and
output a signal to an ion beam mill controller to terminate said ion beam de-layering upon said change exceeding said designated threshold.
